(19) United States
(12) Patent Application Publication
(10) Pub. No.: US 2025/0164581 A1
(43) Pub. Date: May 22, 2025

(54) PORTABLE CONNECTOR TESTING DEVICE AND SYSTEM

(71) Applicant: Illinois Tool Works Inc., Glenview, IL (US)

(72) Inventors: Bryan HAWKES, Birmingham (GB); Malcolm WILLIAMS, Worcester (GB)

(21) Appl. No.: 18/953,542

(22) Filed: Nov. 20, 2024

(30) Foreign Application Priority Data
Nov. 20, 2023 (GB) 2317741.3

(51) Int. Cl. G01R 31/66; G01R 1/067; G01R 1/28

(52) U.S. Cl. CPC G01R 31/66; G01R 1/06788; G01R 1/28

(57) ABSTRACT

Aspects of the disclosure relate to a portable connector testing device and a potable connector testing system. The portable connector testing device comprises: a connector testing module comprising at least two test connectors, wherein at least one test connector of the at least two test connectors is configured to receive a connector to be tested, the connector being electrically connected between the at least two test connectors; a measurement module for testing an electrical property of the received connector; a power module for outputting an electrical power to the connector testing module and the measurement module; and an outer casing comprising an inner cavity for accommodating the power module, connector testing module, and measurement module, at respective positions within the inner cavity with said connector testing module accessible through an opening of the outer casing.

### RELATED APPLICATIONS

The present application claims the benefit of United Kingdom (GB) Patent Application No. 2317741.3, filed Nov. 20, 2023, entitled “Portable Connector Testing Device and System.” The entirety of United Kingdom (GB) Patent Application No. 2317741.3 is expressly incorporated herein by reference.

### FIELD OF THE DISCLOSURE

This disclosure relates to a portable connector testing device, and system.

### BACKGROUND

Components used in electronic systems must adequately perform during use. For example, wires and connectors (e.g. a crimp connector) in electronic systems must have appropriate electric properties, as well as sufficient physical properties (e.g. resilience to external forces during use). Typically, an electrical connector may be tested via a lab-based, multistep, process. In this sense, it will be appreciated that ‘connector’ means a combination of the connector and an electrical conductor to which it is attached, such as by crimping. For example, the connector may be first visually inspected by an engineer, then subjected to a conductance test (e.g. a minimum/maximum current, and/or voltage test), and a physical test such as a tensile strength test. Results of such tests/calibrations may be used to determine whether the connector is suitable for use, such as in a particular use environment e.g. in a harsh environment, aerospace, or military applications.

However, such lab-based set ups are large, and therefore cannot be transported or used in the field by an engineer, which can cause large delays in the maintenance and/or repairing of equipment. Further, because there is no single type of connector for use in all applications, existing connector testing equipment can be complex, and unwieldy, in order to account for different connector types.

Examples disclosed herein may address one or more of the above problems.

### SUMMARY OF THE DISCLOSURE

In accordance with the present disclosure there is provided a portable connector testing device and system as claimed in the appended claims.

According to a first aspect there is provided a portable connector testing device, the portable connector testing device comprising: a connector testing module comprising at least two test connectors, wherein at least one test connector of the at least two test connectors is configured to receive a connector to be tested, the connector being electrically connected between the at least two test connectors; a measurement module for testing an electrical property of the received connector; a power module for outputting an electrical power to the connector testing module and the measurement module; and an outer casing comprising an inner cavity for accommodating the power module, connector testing module, and measurement module, at respective positions within the inner cavity with said connector testing module accessible through an opening of the outer casing.

In some embodiments, the at least two test connectors each comprise a conductive bar. In some embodiments, a portion of the conductive bar may be physically exposed for electrical connection to a conductor/connector.

Optionally, the at least two test connectors may be physically arranged within the connector testing module with an elongate axis of each conductive bar being substantially parallel with respect to an elongate axis of another test connector of the at least two test connectors.

In some embodiments, at least one of the at least two test connectors may comprise one or more connector connection points for receiving the connector.

Optionally, each of the one or more connection points may be for receiving a respective connector type.

In some embodiments, the connector testing module may comprise a fixing plate. The at least two test connectors may be affixed to the fixing plate.

In some embodiments, the portable connector testing device may comprise a drawer arrangement. The drawer arrangement may be retractable with respect to the outer case. The connector testing module may be accommodated on the drawer arrangement.

In some embodiments, the portable connector testing device may comprise a control module. The control module may be configured to control the output of the power module that is delivered to the connector testing module, during use.

Optionally, the control module may comprise one or more of: a current adjustment module for adjusting a current output by the power module; a power cutoff module for halting the delivery of the output of the power module to one or more of the connector testing module and the measurement module; a power switch to activate the control module; and a voltage limit module for limiting a voltage applied to the connector testing module by the power module to a preset value.

Optionally, the control module may be configured to be removable from the portable connector testing device during use.

In some embodiments, the outer casing may comprise a front panel. The front panel may be removable from the outer casing to expose the inner cavity of the outer casing. In response to the front panel being removed from the outer casing, one or more of the power module, the connector testing module, and the measurement module may be exposed from the inner cavity and may be accessible by a user.

Optionally, the outer casing may comprise a rear panel, located at an opposing face to the front panel of the outer casing. The rear panel may be selectively removable from the outer casing to expose the inner cavity of the outer casing. In response to the rear panel being removed from the outer casing, one or more of the power module, the connector testing module, and the measurement module may be exposed from the inner cavity and may be accessible by the user.

Optionally, one or more of the front panel and the rear panel may be fastened to the outer casing using at least one quick release fastener.

In some embodiments, the power module may be configured to receive power from one or more of: a power supply external to the portable connector testing device; and a power supply internal to the portable connector testing device.

According to another aspect, there is provided a portable connector testing system, comprising: a portable connector testing device as disclosed herein; and a testing device external to the portable connector testing device; wherein, an outer casing of the portable connector testing device is configured to support the testing device external to the portable connector testing device so as to stack with the testing device external to the portable connector testing device.

### BRIEF DESCRIPTION OF THE DRAWINGS

Embodiments of the disclosure are further described hereinafter with reference to the accompanying drawings, in which:

FIGS. 1a-1b show a schematic illustration of a connector, conductor, and formation of a coupling between the connector and the conductor;

FIG. 2 shows a schematic illustration of a portable connector testing device according to an embodiment;

FIG. 3 shows a schematic illustration of a connector testing module according to an embodiment;

FIGS. 4a-4b show schematic illustrations of a portable connector testing device according to an embodiment; and

FIG. 5 shows a schematic illustration of a portable connector testing system according to an embodiment.

### DETAILED DESCRIPTION

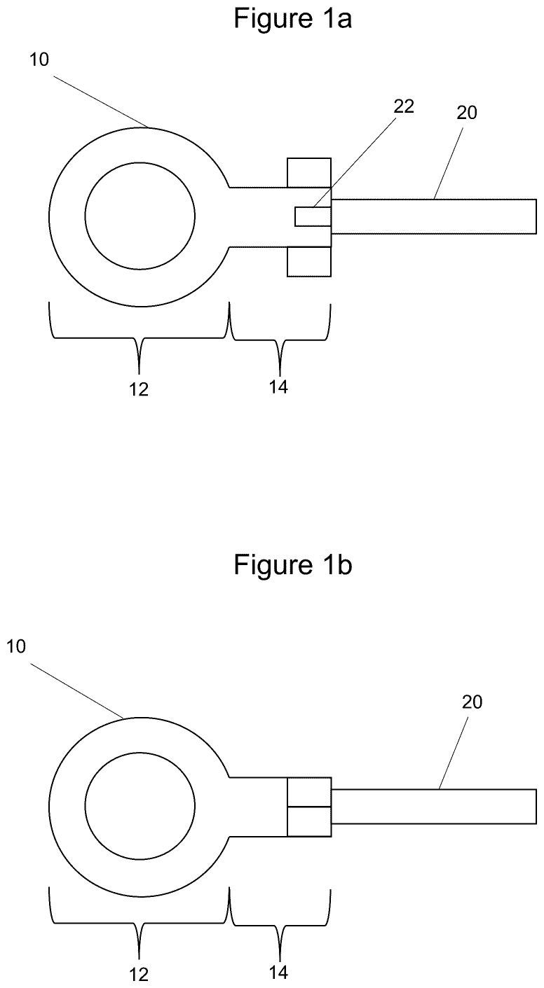

Examples disclosed herein relate to a portable connector testing device. With reference to FIGS. 1a-1b, there is shown a schematic illustration of a connector 10, a conductor 20, and formation of a coupling between the connector 10 and the conductor 20. The connector 10 may comprise a coupling portion 12, and a conductor connection portion 14. The coupling portion 12 may be configured to couple with and/or be received by a corresponding fitting in an electrical system. In this way, the coupling portion 12 may comprise an electrically conductive material. In the example illustrated in FIGS. 1a-1b, the coupling portion 12 corresponds to a lug crimp. As such, the coupling portion 12 may be configured to couple with a nut and bolt configuration. For example, the bolt may pass through an opening of the coupling portion 12 and the configuration may be secured using the bolt, received on a threaded portion of the bolt. However, the coupling portion 12 may correspond to any one or more of a lug crimp, a ring crimp, a fork crimp, a pin crimp and the like.

The conductor connection portion 14 may be configured to form a connection with a conductor 20. In this way, the conductor connection portion 14 may comprise an electrically conductive material. The conductor connection portion 14 may comprise a deforming section. The deforming section may be configured to be deformed to create an mechanical and electrical connection between the conductor connection portion 14 (i.e. the deforming section thereof) and a conductor 20. For example, during assembly of a connection/coupling between the connector 10 and the conductor 20, a conducting portion 22 of the conductor 20 may be located at a feeding portion of the deforming section. For example, in FIG. 1a, the deforming section comprises two tab/deforming portions. However, the deforming section may not be so limited. As such, the deforming section may comprise one or more tab/deforming portions. In some examples, the one or more tab/deforming portions may comprise one or more linear and/or arcuate portions. Using an appropriate tool, for example, a crimping tool, the deforming section may be deformed by a force exerted by the appropriate tool (initially exerted by a user and/or machine) to contact the conduction portion 22 of the conductor 20. In this way, an electrical connection is formed between the connector 10 and the conductor 20. As such, FIGS. 1a-1b illustrate a before and after regarding forming the connection between the connector 10 and the conductor 20, as can be seen from the deformation of the tab/deforming portions. That is, FIG. 1a illustrates a conducting portion 22 of a conductor 20 located at the feeding portion of the deforming section, while FIG. 1b illustrates tab/deforming portions having been deformed to couple with the conducting portion 22 of the conductor 20. In some examples, the tab/deforming portion of the connector 10 may couple to one or more of the conducting portion 22 of the conductor 20 and an insulation portion of the conductor 20 (i.e. a wire insulating portion).

In the example of FIGS. 1a-1b, the conductor 20 is in the form of a single strand wire. However, the conductor 20 may not be so limited. That is, the conductor 20 may comprise one or more of a single strand wire and a multistrand (i.e. two or more) wire. By way of the features disclosed herein, a portable device is provided to test such connections. From herein, the term “connector” means a combination of the connector 10 and an electrical conductor 20 to which it is attached, such as by crimping

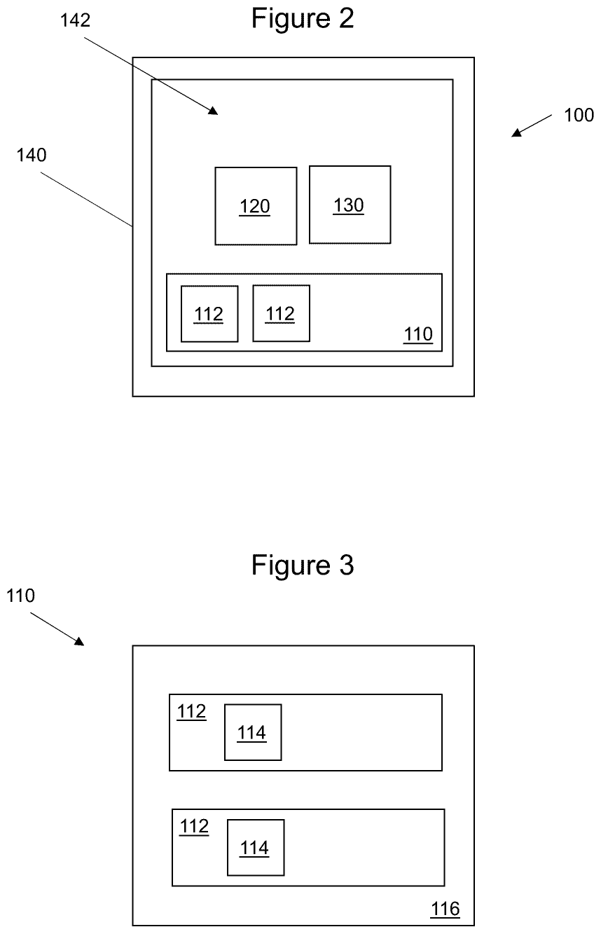

With reference to FIG. 2, there is shown a schematic illustration of a portable connector testing device 100 according to an embodiment of the invention. The portable connector testing device 100 may be configured for use in field environments, such as manufacturing facilities, local to equipment, or the like. For example, the portable connector testing device 100 may be configured for use where a user/engineer may be required to test a connector10 (e.g. a crimp connector), and a connection of the connector 10 to a conductor 20, before use in an electronic system and/or during a fault finding exercise, remote from a laboratory testing set up (e.g. remote field-use for aerospace technology).

The portable connector testing device 100 comprises a connector testing module 110, a measurement module 120, a power module 130, and an outer casing 140.

The connector testing module 110 comprises at least two test connectors 112. At least one test connector of the at least two test connectors 112 is configured to receive a connector 10 (as shown in FIG. 1) to be tested. For example, the at least one test connector 112 may be configured to mechanically and electrically couple with the connector 10 to be tested. In this way, the portable connector testing device 100 may subject the connector 10 to be tested to a coupling substantially the same to those when in use, thereby providing suitable testing conditions. By coupling the connector 10 to a test connector 112 a temporary electrical connection between the at least two test connectors 112 and the conductor 10 may be formed. For example, the connector 10 to be tested may be coupled to a conductor 20 (e.g. a wire), as illustrated and described in relation to FIGS. 1a-1b. The conductor 20 may extend between the at least two test connectors 112 to permit an electrical current to flow from a first test connector of the at least two test connectors 112, through the connector 10 to be tested and the conductor 20 (and the connection therebetween), to a second test connector of the at least two test connectors 112, so as to form part of a circuit. In this way, the portable connector testing device 100 may be configured for a current to flow through a connection/coupling between the connector 10 to be tested and the conductor 20 so as to test the electrical properties of the connection. In some examples, the at least two connectors 112 may each configured to receive respective connectors 10 to be tested, and thereby may permit the testing of a plurality of connectors 10 (and their respective connection to a conductor 20) at the same time. For example, each of the connectors 10 may be received by respective test connecters 112 and may be coupled to one another via a conductor 20. While the illustrated device 100 of FIG. 2 comprises two test connectors 112, in other embodiments the system 1000 may comprise three or more test connectors 112.

The measurement module 120 is configured to test an electrical property of the received connector. That is, by receiving the connector 10, the measurement module 120 may be configured to test the electrical property of the connection between the connector 10 and the conductor 20. For example, the measurement module 120 may be configured to measure one or more of a current, voltage, resistance, capacitance, conductance, frequency, temperature and inductance of the connector 10 and the connection formed to the conductor 20. The measurement module 120 may comprise one or more individual measurement devices to measure respective quantities. For example, the measurement module 120 may comprise one or more of an ammeter, a voltmeter, an ohmmeter, an oscilloscope, a thermometer etc. In some examples, the measurement module 120 may be formed of a single device configured to measure one or more electrical properties of the connector. For example, the measurement module 120 may comprise a multimeter.

The power module 130 is configured to output an electrical power to the connector testing module 110 and the measurement module 120. The power module 130 may be configured to output an electrical power having specific properties. For example, the power module 130 may be configured to output a direct current (DC), and/or an alternative current (AC). In addition, the power module 130 may be configured to output an electrical power having specific values for at least one of a current, voltage, and frequency. In some examples, the specific value may be fixed, or may be altered by a user. The power module 130 may be configured to receive power from one or more of a power supply external to the portable connector testing device 100; and a power supply internal to the portable connector testing device 100. For example, the power supply external to the portable connector testing device 100 may be a mains supply of electrical power and/or an electrical generator. The power supply internal to the power connector testing device may be one or more battery and/or a fuel cell. Advantageously, the power supply internal to the portable connector testing device 100 and/or the power supply external to the portable connector testing device 100 being an electrical generator may improve the portability and versatility of the portable connector testing device 100. In this way, the portable connector testing device 100 may be used in remote locations.

In some examples, the portable connector testing device 100 may comprise a control module (not shown). The control module may be configured to control the output of the power module 130, that may be delivered to the connector testing module 110, during use. In some examples, the control module may be operated by a user to configure the output delivered to the connector testing module 110. As such, the control module may comprise a user interface into which user inputs may be received. For example, the user interface may comprise one or more of a button, a rotating dial, a touchscreen, and an image capturing device.

In some examples, the control module comprises one or more of: a current adjustment module; a power cutoff module; a power switch; and a voltage limit module. The current adjustment module may be configured for adjusting a current output by the power module 130. For example, using the current adjustment module, a user may vary the current delivered to a connector 10 to be tested and, as such, subject the connector to a minimum and maximum current value that the connector 10 may be expected to perform with. The power cutoff module may be configured to halt the delivery of the output of the power module 130 to one or more of the connector testing module 110 and the measurement module 120. For example, use of the power cutoff module may electrically disconnect the components of the portable connector testing device 100. For example, using the power cutoff module, a user may immediately prevent any further power being output by the power module 130 to any component of the portable connector testing device 100. The power switch may be configured to activate the control module. For example, the power switch may comprise an active state and an inactive state. In the active state, the power switch may connect the control module to the power module 130, the measurement module 120 and the connector testing module 110. In the inactive state, the power switch may disconnect the control module from the power module 130, the measurement module 120 and the connector testing module 110. The voltage limit module may be configured to limit a voltage applied to the connector testing module 110 by the power module 130 to a preset value. The voltage limit module may comprise one or more resistors, capacitors, transformers, bipolar junction transistors, BJT, and/or metal oxide semiconductor field effect transistors, MOSFET, to form a voltage regulator which may regulate the output delivered to the connector testing module 110 to not exceed the preset value. The preset value may be determined based on a maximum voltage that may be safely received by components of the portable connector testing device 100. One or more of the current adjustment module; the power cutoff module; the power switch; and the voltage limit module may be interacted with by a user via the user interface of the control module.

The power cutoff module and the voltage limit module may provide a safety mechanism, so as to protect the portable connector testing apparatus and the components therein. For example, a user may notice, using the measurement module 120, that a connector 10 to be tested and/or the connection between the connector 10 and the conductor 20, may be defective and, therefore, may be dangerous to be in connection with the two or more test connectors 112. As such, the user may operate the power cutoff module to halt further delivery of the output of the power module 130 to the connector testing module 110 and the measurement module 120. As another example, an inexperienced user may be operating the portable connector testing device 100 and, when varying a voltage output by the power module 130, either by using the control module and/or the power module 130, the inexperienced user may select a voltage that may be unsafe to the user and/or the portable connector testing device 100. As such, the voltage limit module imposes a voltage value that cannot be exceeded by the output of the power module 130 to ensure user and device safety.

The control module, along with the other components of the portable connector testing device 100, may be accommodated within the inner cavity 142 of the outer casing 140. During use, the control module may be accessible to a user. In some examples, the control module may be removable from the portable connector testing device 100 during use. In this way, usability of the portable connector testing device 100, may be improved, because a user may remove the control module from the portable connector testing device 100 and locate the control module in a location that may be most convenient and/or safe. The control module may be connected to the power module 130 by any one or more of a wired and wireless connection. For example, the control module may comprise a communication module. The communication module may be configured to wirelessly transmit (e.g. via Bluetooth or radio frequency protocols) a user input received by the control module to any one or more of the components of the portable connector testing device 100. In some examples, the control module may comprise a wire in connection with any one or more of the components of the portable connector testing device 100.

The outer casing 140 comprises an inner cavity 142 suitable for accommodating the connector testing module 110, power module 130, and measurement module 120, at respective positions within the inner cavity. The connector testing module 110 is accessible through an opening of the outer casing 140. In some examples, one or more of the components of the portable connector testing device 100 may be fixed into their respective position within the inner cavity 142. For example, one or more of a locking screw and a hook and loop fixing (e.g. Velcro®) may be used to fix one or more components of the portable connector testing device 100 in their respective position within the inner cavity 142. In this way, the portability of the portable connector testing device 100 may be improved and the probability of the components of the portable connector testing device 100 being knocked loose, and/or being damaged during transit may be reduced.

In some examples, one or more components of the portable connector testing device 100 may be integral to the inner cavity 142. For example, the one or more components may be formed as part of an inner wall of the inner cavity 142. In some examples, the inner cavity 142 may comprise one or more of a shelf, a rack, and a drawer arrangement, for accommodating the components of the portable connector testing device 100. In this way, the respective position of the components of the portable connector testing device 100 within the inner cavity 142 may be configured by a user.

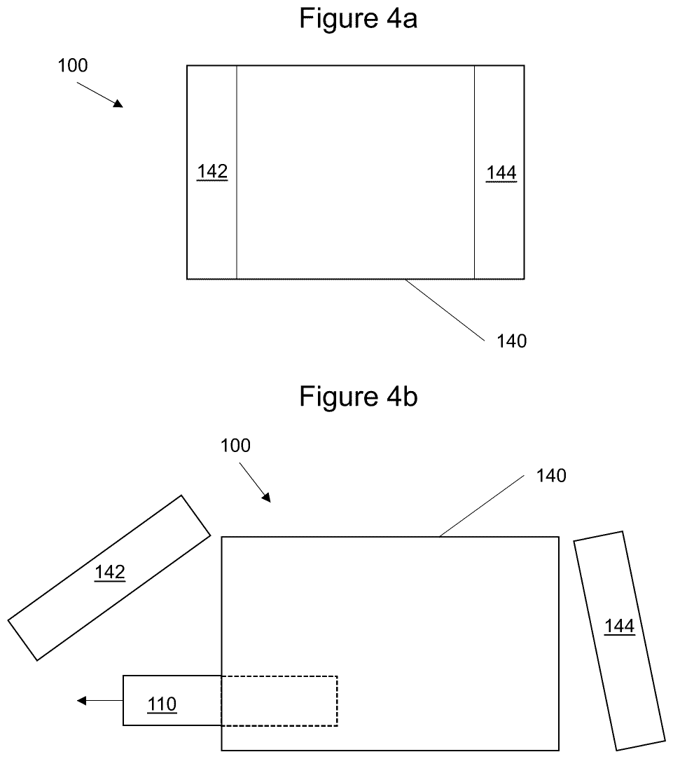

The shelf may be configured to support a component placed on a supporting surface of the shelf. The rack may be configured to receive and couple with a component of the portable connector testing device 100. For example, the rack may comprise one or more features, such as a protrusion, prong, or the like, configured to engage with the component of the portable connector testing device 100. The portable connector testing device 100 may comprise a drawer arrangement. The drawer arrangement may be retractable with respect to the outer case. For example, the drawer arrangement may be slidably coupled to the portable connector testing device 100. In this way, a user may be able to pull the drawer such that any component situated thereon may be exposed from one or more of the inner cavity and the outer casing 140. For example, the connector testing module 110 may be accommodated on the drawer arrangement and, by way of a user interacting with the drawer arrangement the connector testing module 110 may be accessible through an opening of the outer casing 140. This can be seen schematically illustrated in FIG. 4b. That is, a user may pull (see the left-pointing arrow in FIG. 4b) the drawer arrangement outside of a space occupied by the outer casing 140

Turning to FIG. 3, a schematic illustration of the connector testing module 110 is shown. The connector testing module 110 may be the same connector testing module 110 as illustrated in FIG. 2, shown from a different view (e.g. top-down in FIG. 3, while front-on in FIG. 1). The connector testing module 110 comprises the at least two test connectors 112, wherein at least one test connector of the at least two test connectors 112 is configured to receive a connector 10 to be tested (the connection of which to a conductor 20, to be tested). The at least one connector 112 configured to receive the connector 10 to be tested may comprise one or more connection points 114 for receiving the connector 10 (i.e. mechanically and electronically). In some examples, each of the one or more connection points 114 may suitable for receiving/coupling a respective connector 10 type. The connector 10, the connection thereof to a conductor 20 which is to be tested, may be a crimp connector and, therefore, the connection point 114 may correspond to the specific crimp connector fitting. For example, the respective connector type may comprise one or more of a lug crimp, a ring crimp, a fork crimp, a pin crimp and the like. As a non-limiting example, the connector 10 to be tested may be a pin crimp and, as such, the connection point may be a socket into which the pin crimp may be received. As another nonlimiting example, the connector 10 to be tested may be a lug crimp, as is illustrated in Figured 1a-1b, and, as such, the connection point may be a clamp and/or bolt for coupling to the coupling portion 12 (i.e. the lug) of the lug crimp. Therefore, by providing one or more connection points 114, the portable connector testing device 100 may be capable of being connected with a plurality of connectors 10 for testing and, therefore, the usability of the portable connector testing device 100 may be increased. Further, by each of the one or more connection points 114 being for receiving a respective connector type, the versatility of the portable connector testing device 100 may be improved. Further still, performing a visual inspection of the connectors to be tested may be facilitated as the connectors 10 may be fixed in place.

At least one of the at least two test connectors 112 may comprise a conductive bar. In this way, the conductive bar may be elongate so as to comprise a dimension greater than one or more other dimensions. For example, the conductive bar may comprise a length dimension greater than a width dimension and/or a height dimension of the conductive bar. In this way, the conductive bar may be in the form of a conductive ribbon, a conductive cuboid, or the like. In some examples, a portion of the conductive bar may be physically exposed for electrical connection to a conductor 20 and/or a connector 10. Advantageously, a conductive bar may provide an enlarged region in which the one or more connector points may be situated. In this way, multiple connection points 114 may be accommodated on the conductive bar. Further, in the scenario whereby the connector points may be for receiving a respective connector type, the enlarged region of the conduction bar enables multiple connections to a number of connector types. As such, the portable connector testing device 100 may have increased versatility, especially when being used in remote locations.

In some examples, such as that shown in FIG. 3 the at least two test connectors 112 may each comprise a conductive bar. The at least two test connectors 112 may be arranged within the connector testing module 110, within the portable connector testing device 100. In some examples, the at least two test connectors 112 may be physically arranged within the connector testing module 110 with an elongate axis of each conductive bar being substantially parallel with respect to an elongate axis of another test connector of the at least two test connectors 112, as is illustrated in FIG. 3. In this way, the at least two test connectors 112 may be arranged on the connector testing module 110 in a space saving, and space-efficient manner. Due to this, the overall dimensions of the portable connector testing device 100 may be reduced such that the portable connector testing device 100 may have improved portability (i.e. ease of moving the portable connector testing device 100 from a first location to a second location).

In any of the above examples, the connector testing module 110 may comprise a fixing plate 114. The fixing plate 114 may be configured to receive and mechanically couple to one or more components of the connector testing module 110. For example, the at least two test connectors 112 may be affixed to the fixing plate 114. The one or more components may be affixed to the fixing plate 114 by any one or more of a fixing screw, an adhesive, a hook and loop fixing, or the like. In some examples, the fixing plate 114 may be fixed to the drawer arrangement.

The fixing plate 114 may comprise a rigid fixing surface, to which the one or more components of the connector testing module 110 may be affixed. In this way, a relative position of components fixed to the fixing plate 114 may remain constant and repeatability of testing conditions may be improved. Further, by fixing one or more components of the connector testing module 110 to the fixing plate 114, the one or more components may be less likely to move, especially when the portable connector testing device 100 is being transported. In this way, the portable connector testing device 100 may have improved portability and improved robustness. Further still, performing a visual inspection of the connectors 10 to be tested may be facilitated as the connectors 10 may be fixed in place.

FIGS. 4a-4b show a schematic illustration of a portable connector testing device 100 according to an embodiment. FIG. 4a-4b may illustrate the same portable connector testing device 100 as that shown in FIG. 2, shown from a side view (i.e. rotated) 90°. The outer casing 140 may be configured to protect the components accommodated within the inner cavity 142. As such, the outer casing 140 may be formed of a material resilient to deformation. For example, the outer casing 140 may be formed of one or more of: a plastic, metal, and wood. The outer casing 140 may comprise one or more reinforcing members, which may be arranged along any one or more of a face, edge, and corner of the outer casing 140. The outer casing 140 may comprise an upper surface shaped such that the outer casing 140 may be configured to support a device external to the portable connector testing device so as to stack with the device external to the portable connector testing device. In some examples, the upper surface of the outer casing 140 may be substantially flat to enable the device external to the portable connector testing device to stack atop the portable connector testing device 100. In some examples, the upper surface may comprise one or more features to enable the device external to the portable connector testing device to stack atop the portable connector testing device 100. For example, the one or more features may comprise one or more depressions and protrusions in the upper surface of the outer casing 140 to receive the device external to the portable connector testing device.

In some examples, the outer casing 140 may comprise one or more wheels (not shown). For example, one or more wheels may be coupled to a lower surface of the outer casing 140. In this way, a user may not be required to carry the portable connector testing device 100 when transporting the portable connector testing device 100 and, as such, the one or more wheels may improve the portability of the portable connector testing device 100.

The outer casing 140 may comprise a front panel 142. The front panel 142 may be removable from the outer casing 140 to expose the inner cavity of the outer casing 140. In response to the front panel 142 being removed from the outer casing 140, one or more of the power module 130, the connector testing module 110, and the measurement module 120 (and the control module) may be exposed from the inner cavity and may be accessible by a user. For example, by removing the front panel 142, a user may be able to use the components of the portable connector testing device 100 and perform testing for one or more connectors to be tested.

In some examples, such as that illustrated in FIGS. 4a-4b, the outer casing 140 may comprise a rear panel 144. The rear panel 144 may be located at an opposing face to the front panel 142 of the outer casing 140. The rear panel 144 may be removable from the outer casing 140 to expose the inner cavity of the outer casing 140. In response to the rear panel 144 being removed from the outer casing 140, one or more of the power module 130, the connector testing module 110, and the measurement module 120 (and the control module) may be exposed from the inner cavity and may be accessible by the user. For example, by removing the rear panel 144, located at an opposite face of the outer casing 140, a user may be able to access the components of the portable connector testing device 100. For example, as the rear panel 144 may be located at an opposite face of the outer casing 140 to the front panel 142, removal of the rear panel 144 may provide a user access to the rear of the one or more components of the portable connector testing device 100. For example, removal of the rear panel 144 may allow a user to configure wiring associated with one or more of the components of the portable connector testing device 100. For example, removal of the rear panel 144 may allow a user to connect the power module 130 to an external power supply (e.g. mains power and/or electrical generator).

As an example, one or more of the front panel 142 and the rear panel 144 may be installed on the outer casing 140 while the portable connector testing device 100 is being transported and may be removed by a user during use of the portable connector testing device 100. In this way, when one or more of the front panel 142 and the rear panel 144 are installed on the outer casing 140, the components of the portable connector testing device 100 may be sealed from an environment external to the portable connector testing device 100. As such, the front panel 142 and/or the rear panel 144, while installed, as illustrated in FIG. 4a, may protect the components of the portable connector testing device 100. Further, one or more of the front panel 142, the rear panel 144, and the outer casing 140 may comprise a seal portion. The seal portion may be located on an area of the front panel 142, rear panel 144, and the outer casing 140 that couples with another component (e.g. a portion of the front panel 142 that couples to the outer casing 140, a portion of the rear panel 144 that couples to the outer casing 140, and/or portions of the outer casing 140 that couple to the front panel 142 and the rear panel 144, respectively). The seal portion may comprise a rubberised material. The seal may be one or more of airtight, dustproof, and waterproof.

One or more of the front panel 142 and the rear panel 144 may attach to the outer casing 140 in a way that they may be removed and re-installed without damaging the front panel 142, the rear panel 144, and/or the outer casing 140. In some examples, one or more of the front panel 142 and the rear panel 144 may be fastened to the outer casing 140 using at least one quick release fastener. For example, the at least one quick release fastener may comprise a lever configurable in a locked and an unlocked state. In this way, one or more of the front panel 142 and the rear panel 144 may be easily removed from the outer casing 140 and, therefore, improve the usability of the portable connector testing device 100.

In some examples, as illustrated in FIG. 4b, the front panel 142 and rear panel 144 may be completely removable from the outer casing 140. That is, the front panel 142 and the rear panel 144 may be completely detached from the outer casing 140, when removed from the outer casing 140. In this way, a user may freely access the components of the portable connector testing device 100. In alternative examples, one or more of the front panel 142 and rear panel 144 may be attached to the outer casing 140 via one or more hinges. As such, when the front panel 142 and/or the rear panel 144 are removed from the outer casing 140, they may pivot about the one or more hinges to expose components of the portable connector testing device 100 for use. In this way, misplacing the front panel 142 and/or the rear panel 144 may be prevented.

While FIGS. 4a-4b illustrate a portable connector testing device 100 having both a front panel 142 and a rear panel 144, the portable connector testing device 100 may comprise one of the front panel 142 and the rear panel 144. For example, access to the components of the portable connector testing device for performing tests on a connector to be tests and configuring the wiring (e.g. connection to external power supply) of the components of the portable connector testing device may be achieve through one of the front panel 142 and the rear panel 144.

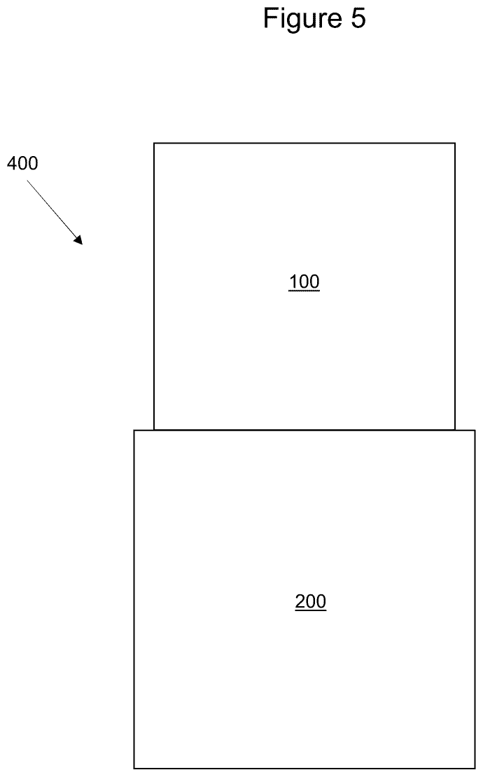

FIG. 5 illustrates a portable connector testing system 400 according to one embodiment. The portable connector testing system 400 comprises a portable connector testing device 100 according to any example disclosed herein in any of the above paragraphs and appended figures; and a testing device 200 external to the portable connector testing device. For example, the testing device 200 external to the portable connector testing device may be a tensometer (e.g. a device for testing the tensile properties of a connector). As such, the portable connector testing system provides a mobile system that may comprise all necessary devices in order to perform sufficient testing (e.g. a visual inspection, an electric property test, and a tensile property test) on a component to ensure it is safe for use. One or more of an outer casing of the portable connector testing device 100 and an outer casing of the testing device 200 external to the portable connector testing device is configured to support the other device of the portable connector testing system 400 so as to stack with the other device of the portable connector testing system 400. That is, an outer casing 140 of the portable connector testing device 100 may configured to support the testing device 200 external to the portable connector testing device so as to stack with the testing device 200 external to the portable connector testing device (e.g. the testing device 200 external to the portable connector testing device may stack on top of the portable connector testing device 100). Further, an outer casing of the testing device 200 external to the portable connector testing device may be configured to support the portable connector testing device 100 so as to stack with the portable connector testing device (e.g. the portable connector testing device 100 may stack on top of the testing device 200 external to the portable connector testing device). In this way, the portable connector testing system according to the present disclosure may form a connector testing tower, while remaining portable and space efficient, and the stacking order thereof may be configurable by a user. For example, in embodiment illustrated in FIG. 5, the outer casing of the testing device 200 external to the portable connector testing device may be configured to support the portable connector testing device 100, and, therefore, the portable connector testing device 100 may stack on top of the testing device 200 external to the portable connector testing device. In some examples, a device (e.g. any one of the portable connector testing device 100 and the testing device 200 external to the portable connector testing device) configured to be at the base of a connector testing tower may comprise one or more wheels. For example, the wheels may be coupled to a lower surface of the outer casing of the device. In this way, the entire portable connector testing system, in the form of a connector testing tower, may be portable.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, and/or characteristics described in conjunction with a particular aspect, embodiment or example of the disclosure are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The disclosure is not restricted to the details of any foregoing embodiments. The disclosure extends to any novel one, or any novel combination, of the features disclosed in this specification (including any accompanying claims, abstract and drawings), or to any novel one, or any novel combination, of the steps of any method or process so disclosed.

What is claimed is:

1. A portable connector testing device comprising:
a connector testing module comprising at least two test connectors, wherein at least one test connector of the at least two test connectors is configured to receive a connector to be tested, the connector being electrically connected between the at least two test connectors;
a measurement module for testing an electrical property of the received connector;
a power module for outputting an electrical power to the connector testing module and the measurement module; and
an outer casing comprising an inner cavity for accommodating the power module, connector testing module, and measurement module, at respective positions within the inner cavity with said connector testing module accessible through an opening of the outer casing.

2. The portable connector testing device of claim 1, wherein the at least two test connectors each comprise a conductive bar.

3. The portable connector testing device of claim 2, wherein the at least two test connectors are physically arranged within the connector testing module with an elongate axis of each conductive bar being substantially parallel with respect to an elongate axis of another test connector of the at least two test connectors.

4. The portable connector testing device of claim 1, wherein at least one of the at least two test connectors comprises one or more connector connection points for receiving the connector.

5. The portable connector testing device of claim 4, wherein each of the one or more connection points are for receiving a respective connector type.

6. The portable connector testing device of claim 1, wherein the connector testing module comprises a fixing plate and the at least two test connectors are affixed to the fixing plate.

7. The portable connector testing device of claim 1, comprising a drawer arrangement, the drawer arrangement being retractable with respect to the outer case, wherein the connector testing module is accommodated on the drawer arrangement.

8. The portable connector testing device of claim 1, comprising a control module configured to control the output of the power module that is delivered to the connector testing module, during use.

9. The portable connector testing device of claim 8, wherein the control module comprises one or more of:
a current adjustment module for adjusting a current output by the power module;
a power cutoff module for halting the delivery of the output of the power module to one or more of the connector testing module and the measurement module;
a power switch to activate the control module; and
a voltage limit module for limiting a voltage applied to the connector testing module by the power module to a preset value.

10. The portable connector testing device of claim 8, wherein the control module is configured to be removable from the portable connector testing device during use.

11. The portable connector testing device of claim 1, wherein the outer casing comprises a front panel, wherein the front panel is removable from the outer casing to expose the inner cavity of the outer casing, and
wherein, in response to the front panel being removed from the outer casing, one or more of the power module, the connector testing module, and the measurement module are exposed from the inner cavity and accessible by a user.

12. The portable connector testing device of claim 11, wherein the outer casing comprises a rear panel, located at an opposing face to the front panel of the outer casing, wherein the rear panel is removable from the outer casing to expose the inner cavity of the outer casing, and
wherein, in response to the rear panel being removed from the outer casing, one or more of the power module, the connector testing module, and the measurement module are exposed from the inner cavity and accessible by the user.

13. The portable connector testing device of claim 11, wherein one or more of the front panel and the rear panel are fastened to the outer casing using at least one quick release fastener.

14. The portable connector testing device of claim 1, wherein the power module is configured to receive power from one or more of:
a power supply external to the portable connector testing device; and
a power supply internal to the portable connector testing device.

15. A portable connector testing system, comprising:
a portable connector testing device according to claim 1; and
a testing device external to the portable connector testing device;
wherein, one or more of an outer casing of the portable connector testing device and an outer casing of the testing device external to the portable connector testing device is configured to support the other device of the portable connector testing system so as to stack with the other device of the portable connector testing system.
